(19) United States
(12) Patent Application Publication
(10) Pub. No.: US 2008/0309225 A1
(43) Pub. Date: Dec. 18, 2008

(54) ORGANIC ELECTROLUMINESCENT DISPLAY DEVICE

(76) Inventors: Masao SHIMIZU, Hitachi (JP); Sukekazu Aratani, Hitachiota (JP); Toshiyuki Matsuura, Mobara (JP); Masahiro Tanaka, Chiba (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/120,532

(22) Filed: May 14, 2008

(30) Foreign Application Priority Data
May 18, 2007 (JP) 2007-132280

(51) Int. Cl. H01J 1/63

(52) U.S. Cl. 313/504

(57) ABSTRACT

The present invention provides an organic electroluminescent display device of high efficiency and high quality, in which the efficiency for injecting electrons from a reflective cathode is improved. The organic electroluminescent display device includes a substrate, a cathode, an organic layer, and an anode. The cathode is formed above the substrate. The organic layer has a luminescent layer and is formed on the cathode. The anode is formed on the organic layer. Light emitted from the luminescent layer is extracted through the anode. The cathode is composed of an alloy containing aluminum as a main component and as a subcomponent at least one metal of oxides whose Gibbs free energies of formation are greater than that of an aluminum oxide.

### BACKGROUND OF THE INVENTION

1. Field of the Invention

The present invention relates to an organic electroluminescent display device having a luminescent layer for emitting light.

2. Description of the Related Art

In general, an active-matrix organic electroluminescent display device has organic electroluminescent elements each of which constitutes a pixel and is connected with a drive element including two to four switching elements (thin film transistors) and a capacitor. The active-matrix organic electroluminescent display device thus enables the organic electroluminescent elements to emit light during a full period of one frame. This makes it unnecessary to increase luminance and makes it possible to extend the operational lives of the organic electroluminescent elements. It is therefore considered that the active-matrix organic electroluminescent display device is advantageous in increasing resolution and screen size.

On the other hand, in an organic electroluminescent display device in which luminescent light is extracted from the back side of a substrate, its aperture ratio is limited when the active matrix type is adopted in which a drive section is provided between the substrate and the organic electroluminescent elements. Especially when such an active matrix organic electroluminescent display device is provided for a large display unit, the width between power lines needs to be increased to suppress luminance variation in pixels due to a voltage drop in the power lines, which leads to the problem that the aperture ratio is extremely reduced.

To avoid the above-mentioned problem, it is considered effective to employ an active-matrix organic electroluminescent display device having a so-called top emission structure in which an upper electrode is made transparent and luminescent light is extracted through the upper transparent electrode. This device does not have a drive section and the like above the upper transparent electrode through which luminescent light is extracted, thus allowing a drastic increase in its aperture ratio.

JP-A-2006-79836 discloses an organic electroluminescent element having such a top emission structure. The organic electroluminescent element has the following anode and cathode. The anode is composed of aluminum (Al) as a main component and of one or more other elements as a subcomponent(s). Each of the subcomponents has a work function relatively smaller than that of aluminum. The cathode is composed of a thin film transistor and a transparent electrode.

### SUMMARY OF THE INVENTION

In JP-A-2006-79836, most of the above elements having smaller work functions are not chemically stable in the atmosphere. Accordingly, when the anode is patterned by wet etching, the surface of the anode is covered with a highly oxidized film. Therefore, the highly oxidized film suppresses injection of electron holes into an organic luminescent layer even if the organic layer and the cathode are laminated above the anode.

In light of a process for forming an element having the top emission structure, a reflective cathode is to be patterned by wet etching or the like in a lithography process. During the wet etching process, the surface of the reflective cathode is thus insulated or contaminated. In this case, even if an electron injection layer or the like is formed on the insulated or contaminated reflective cathode, an electroluminescent efficiency is reduced, or luminescence may not be produced. A study has revealed that this led to the problem of reduced reliability of lighting.

It is, therefore, an object of the present invention to provide an organic electroluminescent display device of high efficiency and high quality, in which the efficiency for injecting electrons from a reflective cathode is improved.

To achieve the above object, the organic electroluminescent display device according to a first aspect of the present invention includes: a substrate; a cathode formed above the substrate; an organic layer having a luminescent layer and formed on the cathode; and an anode formed on the organic layer. Light emitted from the luminescent layer is extracted through the anode. The cathode is composed of an alloy containing aluminum as a main component and a subcomponent at least one metal of metal oxides whose Gibbs free energies of formation are greater than that of an Al oxide.

The organic electroluminescent display device according to a second aspect of the present invention includes: a substrate; a first cathode formed above the substrate; a second cathode formed on the first cathode; an organic layer having a luminescent layer and formed on the second cathode; an anode formed on the organic layer. Light emitted from the luminescent layer is extracted through the anode. The second cathode formed directly under the organic layer includes at least one metal of metal oxides whose Gibbs free energies of formation are greater than that of an Al oxide

The present invention provides an organic electroluminescent display device of high efficiency and high quality, in which the efficiency for injecting electrons from a reflective cathode is improved.

### BRIEF DESCRIPTION OF THE INVENTION

Other objects and advantages of the invention will become apparent from the following description of embodiments with reference to the accompanying drawings in which:

FIG. 1 is a cross sectional view of an organic electroluminescent display element according to an embodiment of the present invention;

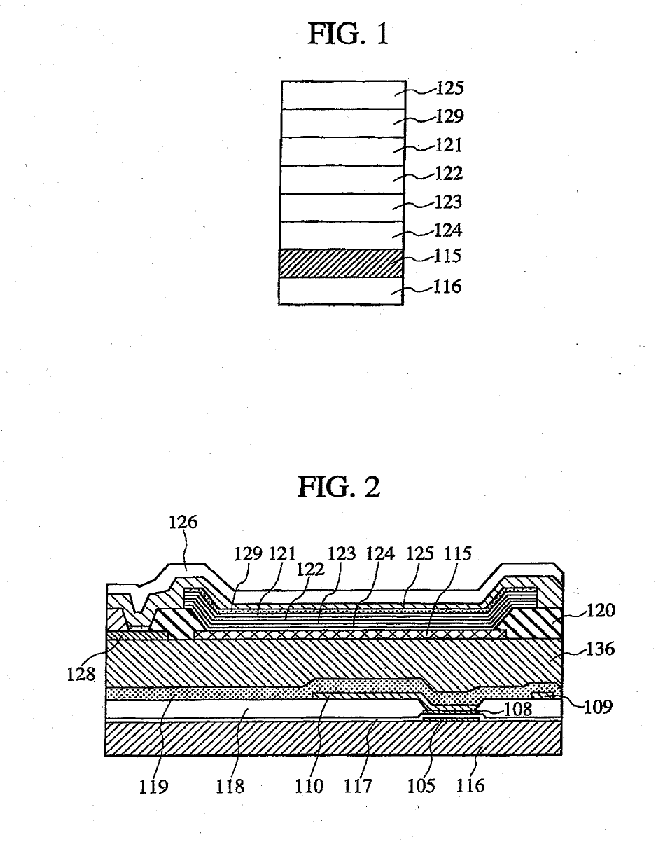

FIG. 2 is a cross sectional view of an organic electroluminescent display device according to the embodiment; and

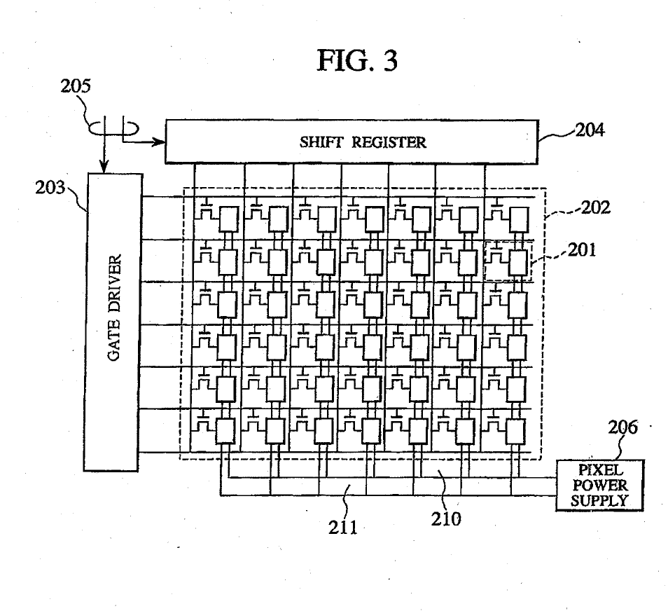

FIG. 3 is a diagram showing a drive circuit provided for the organic electroluminescent display element according to an embodiment.

### DETAILED DESCRIPTION OF THE PREFERRED EMBODIMENTS

A description will be made of first and second embodiments of the present invention. Each of organic electroluminescent display devices according to the first and second embodiments has a top emission structure.

The organic electroluminescent display device according to the first embodiment includes: a substrate; a cathode formed above the substrate; an organic layer having a luminescent layer and formed on the cathode; and an anode formed on the organic layer. Light emitted from the luminescent layer is extracted through the anode. The cathode is composed of an alloy containing aluminum as a main component and as a subcomponent at least one metal of metal oxides whose Gibbs free energies of formation are greater than that of an Al oxide.

The organic electroluminescent display device according to the second embodiment includes: a substrate; a first cathode formed above the substrate; a second cathode formed on the first cathode; an organic layer having a luminescent layer and formed on the second cathode; and an anode formed on the organic layer. Light emitted from the luminescent layer is extracted through the anode. The second cathode formed directly under the organic layer includes at least one metal of metal oxides whose Gibbs free energies of formation are greater than that of an Al oxide.

In the present invention, the reflective cathode is composed of an alloy containing aluminum as a main component and as a subcomponent a metal whose oxidation-reduction curve is located above that of an Al oxide as in the Ellingham diagram. Since the reflective cathode includes the above-mentioned alloy, it becomes easy to remove an insulating film under optimal conditions such as by reverse sputtering using an inert gas, plasma etching using a hydrogen gas, and an ion beam treatment as a pretreatment after the patterning of the reflective cathode. After the organic layer, the anode, and the like are continuingly formed above the cathode in a vacuum state, the efficiency for injecting electrons from the reflective cathode can be improved.

The metal included in the reflective cathode as a subcomponent is limited to Ag, Cu, Rh, W, Co, Mo, Zn, Ni, Ru, Pd, Sn and Si. Two or more types of the above-mentioned elements may be used as the subcomponents of the reflective cathode. In addition, the reflective cathode has a laminated structure including at least two layers. The first cathode, which is provided on the side of the substrate, may include a heretofore known Al—Nd alloy, Al alloy, or the like. The second cathode, which is in contact with the organic layer, includes a metal whose oxidation-reduction curve is located above that of an Al oxide. That metal is used as a thin metal film.

Since the reflective cathode has the above-mentioned laminated structure, it becomes easy to remove an insulating film under optical conditions such as by reverse sputtering using an inert gas, plasma etching using a hydrogen gas, and an ion beam treatment as a pretreatment after the patterning of the reflective cathode having the laminated structure in which at least two layers are laminated. After the organic layer, the anode, and the like are continuingly formed on the cathode in a vacuum state, the efficiency for injecting electrons from the reflective cathode can be improved. In the case of the reverse sputtering using an inert gas, the thin metal film may be sputtered to expose the other reflective cathode provided on the side of the substrate. A material of the thin metal film is limited to Ag, Cu, Rh, W, Co, Mo, Zn, Ni, Ru, Pd, Sn and Si. The thin metal film may include two or more types of the above-mentioned elements.

The organic electroluminescent element includes the cathode, an electron injection layer, an electron transport layer, the luminescent layer, a hole transport layer, a hole injection layer, and the anode, which are laminated in this order. The hole injection layer is desirably formed of a material having an appropriate ionization potential to reduce hole injection barriers between the anode and the hole transport layer. In addition, the hole injection layer desirably serves to eliminate irregularity of the surface of the layer formed directly under the hole injection layer. The material of the hole injection layer may be copper phthalocyanine, a starburst amine compound, polyaniline, polythiophene, or the like. The material of the hole injection layer, however, is not limited to the above materials.

The hole transport layer serves to transport electron holes and inject them into to the luminescent layer. It is therefore desirable that the hole transport layer have a high hole mobility. In addition, it is desirable that the hole transport layer be chemically stable and have a low ionization potential. Furthermore, the hole transport layer desirably has a low electron affinity and a high glass transition temperature. Specifically, the hole injection layer is preferably formed of N,N′-bis(3-methylphenyl)-N,N′-diphenyl-[1,1′-biphenyl]-4,4′-diamine (hereinafter, called TPD), 4,4′-bis[N-(1-naphthyl)-N-phenylamino]biphenyl (hereinafter, called α-NPD), 4,4′,4″-tri(N-carbazolyl) triphenylamine (hereinafter, called TCTA), or 1,3,5-tris [N-(4-diphenylaminophenyl) phenylamino]benzene (hereinafter, called p-DPA-TDAB). The material of the hole transport layer is not limited to the above materials, and two or more types of the above materials may be used in combination as the materials of the hole transport layer.

The luminescent layer refers to a layer in which injected electron holes and electrons are recombined to produce light having a wavelength unique to the material thereof. A host material itself that forms the luminescent layer may emit light, or a dopant material added in a minute amount to the host material may emit light. The host material may be desirably a distyrylarylene derivative (hereinafter, called DPVBi), silole derivative having a benzene ring as a skeleton (hereinafter, called 2PSP), oxiodiaxole derivative having triphenylamine structures at its ends (hereinafter, called EM2), perinone derivative having phenanthrene a group, oligothiophene derivative having triphenylamine structures at both ends (hereinafter, called BMA-3T), perylene derivative (hereinafter, called tBu-PTC), tris(8-quinolinole) aluminum (hereinafter, called Alq), polyparaphenylene vinylene derivative, polythiophene derivative, polyparaphenylene derivative, polysilane derivative, or polyacetylene derivative. The host material is not limited to the above materials, and two or more types of the above materials may be used in combination as the host materials.

The dopant material may be desirably quinacridone, coumarin 6, nile red, rubrene, 4-(dicyanomethylene)-2-methyl-6-(p-dimethylaminostyryl)-4H-pyrane (hereinafter, called DCM), or a dicarbazole derivative. The dopant material is not limited to the above materials, and two or more types of the above materials may be used in combination as the dopant materials.

The electron transport layer serves to transport electrons and inject them into the luminescent layer. It is therefore desirable that the electron transport layer have a high hole-mobility. The electron transport layer is desirably formed of Alq, an oxiodiaxole derivative, a silole derivative, or a zinc benzothiazole complex. The material of the electron transport layer is not limited to the above materials, and two or more types of the above materials be used in combination as the materials of the electron transport layer.

The electron injection layer serves to improve the efficiency for injecting electrons from the cathode into the electron transport layer. The electron injection layer is desirably formed of lithium fluoride, magnesium fluoride, calcium fluoride, strontium fluoride, barium fluoride, magnesium oxide, or aluminum oxide. The electron injection layer is not limited to the above materials, and two or more types of the above materials may be used in combination as the materials of the electron injection layer.

A material used for the anode may be an oxide including an indium oxide as a main component. Especially, it is desirable that the material of the anode be an In₂O₃—SnO₂-based transparent conductive film or an In₂O₃—ZnO-based transparent conductive film. The material of the anode may be a ZnO transparent conductive film. A method for forming the transparent conductive film may be sputtering, electron beam deposition, or ion plating.

In the present invention, the following alloy is used as a material used for the reflective cathode having a single layer. The alloy includes Al as a main component and any of Ag, Cu, Rh, W, Co, Mo, Zn, Ni, Ru, Pd, Sn and Si as a subcomponent. A method for forming the reflective cathode having a single layer may be sputtering, electron beam deposition or ion plating.

The organic electroluminescent display device has a plurality of pixels and thin film transistors for driving the respective pixels and is of an active matrix type. The thin film transistors are formed of polysilicon or amorphous silicon.

The polysilicon thin film transistors make it possible to improve the efficiency of a light emitting section, thus reducing the voltage to drive pixels. This improves reliability of the pixel circuit. Since the pixels can be driven by a low voltage, the size of a pixel power supply can be reduced. In addition, the amorphous thin film transistors make it possible to improve the efficiency of the light emitting section, thus reducing the electric current that drives the thin film transistors and also reducing shifts of threshold voltage values of the thin film transistors.

### EXAMPLES

Next, descriptions will be made of examples of the present invention, comparative examples, methods for forming the organic electroluminescent display device, and evaluation results.

In Example 1, the cathode of the organic electroluminescent display device is composed of an alloy containing Al and Nd as main components. A target is sputtered onto the cathode, which target is composed of a material in which Ni of an Ni oxide whose Gibbs free energy of formation is greater than that of an Al oxide is added to Al. In each Example 1 to 7, a single-layer reflective cathode is used which includes one of mutually different subcomponents. In each Example 8 to 10, a two-layer reflective cathode is used. In Comparative Example 1, the cathode is formed of an Al—Nd alloy that includes the metal of a metal oxide whose Gibbs free energy of formation is less than that of an Al oxide. The layer formation method is described below. As shown in FIG. 1, the organic electroluminescent display device includes: a substrate 116; a reflective cathode 115 formed on the substrate 116; an electron injection layer 124 formed on the reflective cathode 115; an electron transport layer 123 formed on the electron injection layer 124; a luminescent layer 122 formed on the electron transport layer 123; a hole transport layer 121 formed on the luminescent layer 122; a hole injection layer 129 formed on the hole transport layer 121; and an anode 125 formed on the hole injection layer 129. The organic electroluminescent display device has a top emission structure in which light is extracted through the anode 125.

In each example, the reflective cathode 115 with a thickness of 100 nm is formed on the glass-made substrate 116 by sputtering. After the sputtering, the cathode is patterned by wet etching. Then, reverse sputtering using an inert gas, or plasma etching using a hydrogen gas, is performed on the cathode as a pretreatment. Then, the deposition is continued in a vacuum state. After that, as the electron injection layer 124, a lithium fluoride (LiF) film with a thickness of 0.5 nm is formed on the reflective cathode 115 by vacuum deposition and patterned by using a shadow mask. An Alq film with a thickness of 20 nm is then formed on the electron injection layer 124 by vacuum deposition and patterned by using a shadow mask. The Alq film serves as the electron transport layer 123. A film containing Alq and quinacridone with a thickness of 20 nm is formed on the electron transport layer 123 by simultaneous vacuum deposition of Alq and quinacridone. The ratio of the deposition rate of Alq to that of quinacridone is set to 40:1. The film containing Alq and quinacridone is patterned by using a shadow mask and serves as the luminescent layer 122. Next, an α-NPD film with a thickness of 50 nm is formed on the luminescent layer 122 by vacuum deposition. The α-NPD film is then patterned by using a shadow mask.

Each side of a deposition area of the α-NPD film is 1.2 times as large as that of the lower electrode (cathode). The α-NPD film serves as the hole transport layer 121. A layer of copper phthalocyanine is formed on the hole transport layer 121 by vacuum deposition and patterned by using a shadow mask. The layer of copper phthalocyanine has a thickness of 50 nm and serves as the hole injection layer 129.

An IZO (In—Zn—O) film is formed on the hole injection layer 129 by sputtering in a vacuum of 0.8 Pa and at a sputtering output of 0.2 W/cm², with a mixed gas containing Ar and O₂ used as an atmosphere. The IZO film has a thickness of 150 nm and serves as the anode 125. The IZO film is an amorphous oxide film. In the sputtering, a target material having a ratio of 1n/(In +Zn)=0.83 is used. With the above method, an organic electroluminescent element is obtained for each Example 1 to 10 and Comparative Example 1.

In each of the organic electroluminescent elements formed by the above-mentioned formation method for each of Examples 1 to 10 and Comparative Example 1, a current density is measured with a voltage of 7 volts applied. The measurement results are shown in Table 1.

TABLE 1

| | | Current density |
|---|---|---|
| | Cathode | (A/cm² at 7 volts) |
| Example 1 | Al—Nd—Ni | 0.1 |
| Example 2 | Al—Ni | 0.15 |
| Example 3 | Al—Zn | 0.05 |
| Example 4 | Al—W | 0.07 |
| Example 5 | Al—Mo | 0.07 |
| Example 6 | Al—Ru | 0.02 |
| Example 7 | Al—Co | 0.03 |
| Example 8 | Al—Nd/Ni | 0.01 |
| Example 9 | Al—Nd/Zn | 0.008 |
| Example 10 | Al—Nd/Mo | 0.01 |
| Comparative Example 1 | Al—Nd | 0.0001 |

In Comparative Example 1, the current density of the Al—Nd alloy is 0.0001 A/cm². In contrast, the current densities of the organic electroluminescent elements in Examples 1 to 10 are larger than 0.0001 A/cm². It was thus confirmed that, with the use of the metals of metal oxides whose Gibbs free energies of formation are greater than that of an Al oxide, the efficiency of electron injection form the cathode can be improved.

Next, other organic electroluminescent elements having the layer structure shown in FIG. 1 are formed by the above formation method as in the above Examples. Specifically, onto the Al film is sputtered a target composed of only Ni of an Ni oxide whose Gibbs free energy of formation is greater than that of an Al oxide. In Examples 11 and 12, two-layer reflective cathodes are used each of which includes mutually different elements. Of the two layers, the cathode layer in contact with the organic layer is important. The other cathode layer provided on the side of the thin film transistors can be formed of a heretofore known material. In Comparative Example 2, a target composed of only Nd of an Nd oxide whose Gibbs free energy of formation is less than that of an Al oxide is sputtered onto the Al film. In each of the organic electroluminescent elements formed by the above-mentioned formation methods for Examples 11 and 12 and Comparative Examples 2 and 3, a current density is measured with a voltage of 7 volts applied. The measurement results are shown in Table 2.

TABLE 2

| | | Current density | Gibbs free |
|---|---|---|---|
| | | (A/cm² at | energy at room |
| | Cathode | 7 volts) | temperature (kJ/mol) |
| Example 11 | Al/Mo | 0.01 | −668(MoO₃) |
| Example 12 | Al/Ni | 0.01 | −211(NiO) |
| Comparative | Al/Nd | 0.00001 | −1720(Nd₂O₃) |
| Example 2 | | | |
| Comparative | Al/Al | 0.00001 | −1580(Al₂O₃) |
| Example 3 | | | |

The current of the cathode having an Al layer and an Nd layer in Comparative Example 2 and the current density of the cathode having two Al layers in Comparative Example are 0.00001 A/cm². In contrast, the current densities of the cathodes in Examples 11 and 12 are larger than those of the cathodes in Comparative Examples 2 and 3. It was thus confirmed that with the use of the metals of metal oxides whose Gibbs free energies of formation are greater than that of an Al oxide, the efficiency of electron injection form the cathode can be improved. The method for forming the organic electroluminescent display device in the examples will now be described

The thin film transistors are formed of polysilicon. FIG. 2 is a cross sectional view of a pixel area of the organic electroluminescent display device.

First, an amorphous silicon (a-Si) film is formed on the substrate 116 formed of glass by low pressure chemical vapor deposition (LPCVD). The a-Si film has a thickness of 50 nm. Then, the entire surface of the a-Si film is annealed by a laser beam. The laser annealing crystallizes the a-Si film to form a polycrystalline silicon (p-Si) film. Next, the p-Si film is patterned by dry etching to form an active layer of a first transistor, an active layer of a second transistor, and a lower capacitive electrode 105. Next, an SiO₂ film is formed by plasma enhanced chemical vapor deposition (PECVD). The SiO₂ film has a thickness of 100 nm and serves as a gate insulating film 117. Then, a TiW film with a thickness of 50 nm is formed by sputtering and patterned. The TiW film serves as a gate electrode. In addition, a gate line and an upper capacitive electrode 108 are patterned. Next, phosphorus ions are implanted from the upper side of the gate insulating film 117 into the patterned p-Si film by an ion implantation technique. The phosphorus ions are not implanted into an area above which the gate electrode is present. The area, in which the phosphorus ions are not implanted, serves as a channel area. Next, the substrate 116 is subjected to a heat treatment in an N₂ atmosphere to activate impurities (phosphorus) and form an impurity activated region. Then, as a first interlayer insulating film 118, an SiN₂ film is formed on the gate insulating film 117. The SiN₂ film has a thickness of 200 nm. Next, a contact hole is formed in the first interlayer insulating film 118 and a portion of the gate insulating film 117 corresponding to the impurity activated region. In addition, a contact hole is formed in a portion of the first interlayer insulating film 118 located above the gate electrode of the second transistor.

Then, an Al film with a thickness of 500 nm is formed on the first interlayer insulating film 118 by sputtering. A data line 109 and a first power supply line are formed in a photolithography process. In addition, source and drain electrodes of the first transistor and source and drain electrodes of the second transistor are formed. The drain electrode of the first transistor is connected to the lower capacitive electrode 105. The source electrode of the first transistor is connected to the data line 109. The drain electrode of the first transistor is connected to the gate electrode of the second transistor. The drain electrode of the second transistor is connected to the power supply line. The power supply line is connected to the upper capacitive electrode 108. Next, as a second interlayer insulating film 119, an SiNₓ film is formed by PECVD. The SiNₓ film has a thickness of 500 nm. Then, a contact hole is formed above the drain electrode of the second transistor.

A film containing Al and Ni with a thickness of 150 nm is formed on a planarized layer 136 by sputtering. The photolithography process is then performed to form the reflective cathode 115. Next, as an insulating bank 120, SiNₓ is deposited by PECVD. Then, the insulating bank 120 is formed into a forward tapered shape by dry etching using CF₄O₂. Plasma etching, vacuum annealing, and the like are then performed on the exposed surface of the reflective cathode 115 due to the dry etching. After that, each layer is formed by continuous vacuum deposition.

An LiF film is formed on the reflective cathode 115 by vacuum deposition. The LiF film has a thickness of 0.5 nm and serves as the electron injection layer 124. The LiF film with a thickness of 20 nm is patterned with a shadow mask. An Alq film is then formed on the electron injection layer 124 by vacuum deposition. The Alq film serves as the electron transport layer 123. The Alq film is patterned with a shadow mask. A film containing Alq and quinacridone with a thickness of 20 nm is formed on the electron transport layer 123 by simultaneous vacuum deposition of Alq and quinacridone. The ratio of the deposition rate of Alq to that of quinacridone is set to 40:1. The film containing Alq and quinacridone is patterned by using a shadow mask and serves as the luminescent layer 122. Next, an α-NPD film is formed on the luminescent layer 122 by vacuum deposition. The α-NPD film has a thickness of 50 nm. The α-NPD film is patterned with a shadow mask. Each side of a deposition area of the α-NPD film is 1.2 times as large as that of the lower electrode. The α-NPD film serves as the hole transport layer 121. Next, a layer of copper phthalocyanine is formed on the hole transport layer 121 by vacuum deposition and patterned with a shadow mask. The copper phthalocyanine layer has a thickness of 50 nm and serves as the hole injection layer 129. Each side of a deposition area of the copper phthalocyanine layer is 1.2 times as large as that of the lower electrode.

An IZO (In—Zn−O) film is formed on the hole injection layer 129 by sputtering in a vacuum of 0.8 Pa and at a sputtering output of 0.2 W/cm², with a mixed gas containing Ar and O₂ used as an atmosphere. The IZO film has a thickness of 100 nm and serves as the anode 125, which is the upper electrode (second electrode). The IZO film is an amorphous oxide film. In the sputtering, a target material having a ratio of In/(In+Zn)=0.83 is used. The IZO film has a light transmittance of 80%. Next, an SiOₓN_{y} film with a thickness of 50 nm is formed on the anode 125 by sputtering. The SiOₓN_{y} film serves as a protective layer 126.

It was confirmed that the above-mentioned formation method makes it possible to improve the efficiency of the light emitting section, thus reducing the electric current that drives the thin film transistors and also reducing shifts of threshold voltage values the thin film transistors.

For comparison, another organic electroluminescent display device is formed with the reflective cathode composed of an alloy containing Al and Nd, as in Comparative Example 1.

The display devices of Example 2 and Comparative Example 1 shown in Table 1 were evaluated in terms of luminance of emitted light.

A voltage of 7 volts is applied to each element of the display devices. In the display device in Example 2, the reflective cathode composed of an alloy containing Al and Ni is used. In the display device of Example 2, a luminance of 1500 cd/cm² was obtained. In the display device of Comparative Example 1, a luminance of 500 cd/cm² was obtained. It is found out that the display device of Comparative Example 1 hardly emitted light after the voltage was applied to its element for 200 hours.

In addition, a display panel shown in FIG. 3 is experimentally formed. In the display panel, pixels 201 each having a memory cell therein are arrayed in a matrix to form a display area 202. To drive the matrix, data lines are connected with a shift register 204, and gate lines are connected with a gate driver 203. The gate driver 203 and the shift register 204 are controlled by respective control signals and display data. The control signals and display data are supplied to the gate driver 203 and the shift register 204 through input lines 205. EL power supply lines 210 and EL common lines 211 of pixels are collectively connected to a pixel power supply 206.

The luminance of light emitted from the display device of Example 2 was evaluated. The voltage of 7 volts was applied to the element of the display device. In the display device of Example 2, the luminance of 1500 cd/cm² was obtained. The display device of Example 2 makes it possible to improve the efficiency of the light emitting section, thus reducing the voltage to drive pixels. This improves reliability of the pixel circuit. Since the pixels can be driven by a low voltage, the size of the pixel power supply can be reduced.

The thin film transistors are formed of amorphous silicon. The pixel area of the organic electroluminescent display device has the same cross section as that in Example 2. An amorphous silicon (a-Si) film with a thickness of 50 nm is formed on the glass substrate 116 by low pressure chemical vapor deposition (LPCVD).

Next, the a-Si film is patterned by dry etching to form an active layer of a first transistor, an active layer of a second transistor, and a lower capacitive electrode 105.

Next, an SiO₂ film is formed by plasma enhanced chemical vapor deposition (PECVD). The SiO₂ film has a thickness of 100 nm and serves as a gate insulating film 117.

Then, as a gate electrode, a TiW film with a thickness of 50 nm is formed by sputtering and patterned. In addition, a gate line and an upper capacitive electrode 108 are patterned.

Then, phosphorus ions are implanted from the upper side of the gate insulating film 117 into the patterned p-Si layer by an ion implantation technique. The phosphorus ions are not implanted into an area above which the gate electrode is present. The area, in which the phosphorus ions are not implanted, serves as a channel area.

Next, the substrate 116 is subjected to a heat treatment n an N₂ atmosphere to activate impurities (phosphorus) and form an impurity activated region. Then, as a first interlayer insulating film 118, an SiN₂ film is formed on the gate insulating film 117. The SiN₂ film has a thickness of 200 nm. Next, a contact hole is formed in the first interlayer insulating film 118 and a portion of the gate insulating film 117 corresponding to the impurity activated region. In addition, a contact hole is formed in a portion of the first interlayer insulating film 118 located above the gate electrode of the second transistor.

Then, an Al film with a thickness of 500 nm is formed on the first interlayer insulating film 118 by sputtering. A data line 109 and a first power supply line are formed in a photolithography process. In addition, source and drain electrodes of the first transistor and source and drain electrodes of the second transistor are formed. The drain electrode of the first transistor is connected to the lower capacitive electrode 105. The source electrode of the first transistor is connected to the data line 109. The drain electrode of the first transistor is connected to the gate electrode of the second transistor. The drain electrode of the second transistor is connected to the power supply line. The upper capacitive electrode 108 is connected to the power supply line. Next, as a second interlayer insulating layer 119, an SiNₓ film is formed by PECVD. The SiNₓ film has a thickness of 500 nm. A contact hole is formed above the drain electrode of the second transistor.

A film containing Al and Nd with a thickness of 150 nm is formed on a planarized layer 136 by sputtering. Then, an Mo Film with a thickness of 10 nm is formed on the film containing Al and Nd. The photolithography process is then performed to form the reflective cathode 115 having the two layers.

Next, as an insulating bank 120, an SiNₓ is deposited by PECVD. Then, the insulating bank 120 is formed into a forward tapered shape by dry etching using CF₄+O₂Reverse-sputtering using an inert gas is performed on the exposed surface of the reflective cathode 115 due to the dry etching. After that, each layer is formed by continuous vacuum deposition. An LiF film is formed on the reflection cathode 115 by vacuum deposition. The LiF film has a thickness of 0.5 nm and serves as the electron injection layer 124. The LiF film is patterned with a shadow mask. An Alq film with a thickness of 20 nm is then formed on the electron injection layer 124 by vacuum deposition. The Alq film is patterned with a shadow mask and serves as the electron transport layer 123.

A film containing Alq and quinacridone with a thickness of 20 nm is formed on the electron transport layer 123 by simultaneous vacuum deposition of Alq and quinacridone. The ratio of the deposition rate of Alq to that of quinacridone is set to 40:1. The film containing Alq and quinacridone is patterned with a shadow mask and serves as the luminescent layer 122. Next, an α-NPD film is formed on the luminescent layer 122 by vacuum deposition. The α-NPD film has a thickness of 50 nm. The α-NPD film is patterned with a shadow mask. Each side of a deposition area of the α-NPD film is 1.2 times as large as that of the lower electrode. The α-NPD film serves as the hole transport layer 121.

Next, a layer of copper phthalocyanine is formed on the hole transport layer 121 by vacuum deposition and patterned with a shadow mask. The layer of copper phthalocyanine has a thickness of 50 nm and serves as the hole injection layer 129. Each side of a deposition area of the copper phthalocyanine layer is 1.2 times as large as that of the lower electrode. An In—Zn—O (IZO) film is then formed on the hole injection layer 129 by sputtering in a vacuum of 0.8 Pa and at a sputtering output of 0.2 W/cm², with a mixed gas containing Ar and O₂ used as an atmosphere. The IZO film has a thickness of 100 nm and serves as the anode 125 (as a second electrode). The IZO film is an amorphous oxide film. In the sputtering, a target material having a ratio of In/(In+Zn)=0.83 is used. The IZO film has a light transmittance of 80%. Next, an SiOₓN_{y} film with a thickness of 50 nm is formed by sputtering. The SiOₓN_{y} film serves as a protective layer 126.

It should be noted that the thin film transistors may be formed of polysilicon.

It was confirmed that the above-mentioned formation method makes it possible to improve the efficiency of luminescent section, thus reducing the electric current that drives the thin film transistors and also reducing shifts of threshold voltage values of the thin film transistors.

For comparison, another organic electroluminescent display device is formed with the reflective cathode composed of an alloy containing Al and Nd.

Luminances of the display devices were evaluated. A voltage of 7 volts was applied to each element of the display devices. In the display device of Example 10, the reflective cathode has a first layer containing Al and Nd and a second layer containing Mo, in which the first layer is formed on the side of the substrate, and the second layer is formed on the side of the organic layer. In the display device of Example 10, it is found out that a luminance of 1200 cd/cm² could be obtained.

While the invention has been described in its preferred embodiments, it is to be understood that the words which have been used are words of description rather than limitation and that changes within the purview of the appended claims may be made without departing from the true scope and spirit of the invention in its broader aspects.

What is claimed is:

1. An organic electroluminescent display device having a top emission structure, the device comprising:
a substrate;
a cathode formed above the substrate;
an organic layer having a luminescent layer and formed on the cathode; and
an anode formed on the organic layer;
wherein light emitted from the luminescent layer is extracted through the anode, and
wherein the cathode is composed of an alloy containing aluminum as a main component and as a subcomponent at least one metal of metal oxides whose Gibbs free energies of formation are greater than that of an aluminum oxide.

2. An organic electroluminescent display device having a top emission structure, the device comprising:
a substrate;
a first cathode formed above the substrate;
a second cathode formed on the first cathode;
an organic layer having a luminescent layer and formed on the second cathode; and
an anode formed on the organic layer;
wherein light emitted form the luminescent layer is extracted through the anode, and
wherein the second cathode contains at least one metal of metal oxides whose Gibbs free energies of formation are greater than that of an aluminum oxide.

3. The organic electroluminescent display device having a top emission structure according to claim 1, wherein
the metal contained in the cathode as a subcomponent is any of Ag, Cu, Rh, W, Co, Mo, Zn, Ni, Ru, Pd, Sn and Si.

4. The organic electroluminescent display device having a top emission structure according to claim 2, wherein
the metal contained in the second cathode as a subcomponent is any of Ag, Cu, Rh, W, Co, Mo, Zn, Ni, Ru, Pd, Sn and Si.

5. The organic electroluminescent display device having a top emission structure according to claim 1, comprising:
a plurality of pixels; and
a plurality of thin film transistors for driving the respective pixels.

6. The organic electroluminescent display device having a top emission structure according to claim 5, comprising:
the thin film transistors are formed of polysilicon or amorphous silicon.

7. The organic electroluminescent display device having a top emission structure according to claim 2, comprising:
a plurality of pixels; and
a plurality of thin film transistors for driving the respective pixels.
